(19) United States
(12) Patent Application Publication
(10) Pub. No.: US 2009/0167293 A1
(43) Pub. Date: Jul. 2, 2009

(54) DIFFERENTIAL PROBE DEVICE FOR MEASURING ELECTRICAL DIFFERENTIAL SIGNALS AND METHODS FOR MEASURING SIGNALS USING A DIFFERENTIAL PROBE DEVICE

(76) Inventors: Jason A. Swaim, Castle Rock, CO (US); James E. Cannon, Colorado Springs, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/968,254

(22) Filed: Jan. 2, 2008

(51) Int. Cl. G01R 1/067; H01R 43/00

(52) U.S. Cl. 324/149; 73/866.5; 29/876

(57) ABSTRACT

A differential probe device is provided that has a scissor-type configuration that allows the inter-tip ground path length to be very short, thereby ensuring that the probe device will have a small ground inductance. Providing the probe device with a small ground inductance ensures that the ground inductance will not cause the bandwidth of the probe device to be unduly limited, even at higher frequencies. The configuration of the probe device also enables the ground areas on the arms to remain in continuous contact over the range of available span widths between the tips, which also helps to ensure that the ground inductance is kept small and generally fixed. Also, the configuration of the probe device enables the proximal ends of the probe arms to be kept small in size to accommodate DUT layouts having small test features and/or test features that are close together.

### TECHNICAL FIELD OF THE INVENTION

The invention relates to differential probe devices used to measure differential signals on conductors of a device under test (DUT). More particularly, the invention relates to a differential probe having a scissor configuration.

### BACKGROUND OF THE INVENTION

A differential probe device is a device having two arms, sometimes referred to as “substrates” or “blades”, which are mechanically coupled to each other at distal ends of the arms, and electrically conductive tips secured to the proximal ends of the arms. During testing of a DUT, the tips are placed in contact with respective conductors of the DUT for sensing electrical differential signals propagating though the conductors of the DUT. The probe device is typically adjustable to allow the probe tips to be moved closer to and farther away from each other such that a span width between the tips is adjustable to accommodate varying DUT physical layouts. The electrical signals sensed by the tips are passed from the tips to other electrical circuits disposed on the arms that prepare the signals for input to a differential amplifier circuit. The arms are each electrically coupled at the distal ends to respective electrical wires, such as coaxial cables, which receive the amplified differential signals output from the differential amplifier circuit and pass the amplified differential signals to test and measurement equipment, such as an oscilloscope.

Each probe tip of a differential probe device has a ground path and a signal path. The ground paths of the tips must be electrically interconnected. For this reason, each of the arms has an electrical ground area on it that is connected to the respective ground path of the respective tip. These ground areas should be as close to the probe tips as possible so that the inter-tip ground path, sometimes referred to as the ground loop, is as short as possible. One reason for this is that a parasitic inductance, typically referred to as the “ground” inductance, exists which, if it is too large, can result in a voltage potential developing at higher frequencies between a virtual ground plane associated with the ground loop and the probe device's ground. This voltage potential can reduce the voltage signal being measured at the attenuator/amplifier input of the probe device, and thus essentially limits the bandwidth of the probe device at higher frequencies. Locating the ground areas closer to the probe tips helps to ensure that this inter-tip path length is short, which helps to ensure that the ground inductance will remain relatively small, and therefore will not unduly limit the bandwidth of the probe device.

Adjustable differential probe devices incorporate mechanical coupling devices that mechanically couple the arms together in a way that allows the positions of the probe tips to be adjusted relative to each other. These mechanical coupling devices couple the arms together at locations that are typically closer to the distal ends of the arms (the ends of the arms opposite the ends to which the tips are attached) than they are to the proximal ends of the arms (the ends to which the tips are attached). A conductive element, such as a spring made of a conductive material, for example, is then used to electrically connect the ground areas on the arms to each other at a location that is closer to the tips than the location at which mechanical coupling device couples the arms together.

One of the disadvantages of using an electrically conductive element interposed between the arms to interconnect the ground areas on the arms is that the length of the conductive element (e.g., a spring) generally must be compliant in order to maintain the connection between the ground planes as the width of the span between the tips is adjusted. This requirement that the conductive element be compliant generally results in the path between the ground areas being longer than desired, which, as described above, may lead to limitations on the bandwidth of the probe device.

In addition, when smaller span widths are used, this makes it more likely that the conductive element that interconnects the ground areas on the arms will be damaged. This, in turn, may result in performance degradation.

Furthermore, when the conductive element is damaged, the damage is not always apparent to the user, which may result in the person who performs the test erroneously concluding that the DUT is defective, and/or other problems.

Accordingly, a need exists for a differential probe device having a configuration that enables the inter-tip ground path to be as short as possible, even as the span width between the probe tips is adjusted. A need also exists for a differential probe device that has improved performance at higher frequencies.

### SUMMARY OF THE INVENTION

The invention provides a probe device for use in measuring electrical signals on a DUT, as well as methods for manufacturing and using the probe device. The probe device comprises a first arm, a second arm and a coupling mechanism. The first and second arms each have a proximal end and a distal end. The proximal ends of the first and second arms have first and second electrically conductive tips secured thereto. The first and second arms have first and second coupling areas disposed thereon near the proximal ends of the first and second arms, respectively. The first and second coupling areas have first and second electrical ground areas thereon that are electrically connected to the first and second electrically conductive tips. The coupling mechanism couples the first and second arms to each other in a scissor-type configuration with the first and second coupling areas contacting each other. The scissor-type configuration allows the first and second arms to rotate through a range of angles about an axis that is normal to the first and second coupling areas.

The method for manufacturing the probe device comprises providing a probe device having at least a first arm, a second arm and a coupling mechanism, and using the coupling mechanism to couple the first arm and the second arm to each other in a scissor-type configuration that allows the first and second arms to rotate through a range of angles about an axis that is normal to the first and second coupling areas. When the first and second arms are coupled to each other by the coupling mechanism, the first and second coupling areas are in contact with each other. The first and second arms have respective proximal ends and distal ends, with first and second electrically conductive tips secured to the respective proximal ends. The first and second arms have first and second coupling areas, respectively, disposed thereon near the respective proximal ends and first and second electrical ground areas disposed on the first and second coupling areas, respectively.

The method for using the probe to measure electrical signals on a DUT comprises adjusting a span width, W, between first and second electrically conductive tips of a probe device and positioning the probe device such that the first and second electrically conductive tips are in contact with one or more features on the DUT. The span width, W, is adjusted by moving the distal ends of the first and second arms of the probe device toward or away from each other to cause the proximal ends of the first and second arms of the probe device to move toward or away from each other, respectively. The first and second electrically conductive tips are secured to the proximal ends of the first and second arms, respectively. Movement of the distal ends of the arms away from each other results in movement of the proximal ends away each other such that the span width, W, is increased. Movement of the distal ends toward each other results in movement of the proximal ends toward each other such that the span width, W, is decreased.

These and other features and advantages of the invention will become apparent from the following description, drawings and claims.

### BRIEF DESCRIPTION OF THE DRAWINGS

FIG. 1 illustrates a top perspective view of the differential probe device of the invention in accordance with an illustrative embodiment.

FIG. 2 illustrates a top perspective view of the differential probe device shown in FIG. 1 when the distal ends of the arms of the probe device are moved as close together as possible so that the span width between the tips is at a minimum value.

FIG. 3 illustrates a perspective top view of the yoke of the probe device shown in FIGS. 1 and 2.

FIG. 4 illustrates a top perspective view of one of the arms of the probe device shown in FIGS. 1 and 2.

FIG. 5 illustrates a top perspective view of the probe device shown in FIG. 1, but with a sliding mechanism added to the device that may be used by a user to set the span width between the tips at a selected value.

FIG. 6 illustrates a perspective view of the pin of the swivel mechanism shown in FIG. 1.

FIGS. 7A-7C illustrate different views of a probe device in accordance with another illustrative embodiment of the invention.

### DETAILED DESCRIPTION OF ILLUSTRATIVE EMBODIMENTS

In accordance with the invention, a differential probe device is provided that has a scissor-type configuration that allows the inter-tip ground path length to be very short, thereby ensuring that the probe device will have a small ground inductance. This feature of the invention ensures that the bandwidth of the probe device will not be unduly limited by the ground inductance. In addition, the scissor-type configuration of the probe device of the invention enables the ground areas on the substrates to remain in continuous contact with each other regardless of adjustments made in the span width between the tips, and without the use of a spring. This feature of the invention ensures that the ground inductance will be small and substantially unchanged over the entire range of span width adjustments. Keeping the ground inductance small and unchanging over the range of span width adjustments further helps to ensure that the bandwidth of the probe device will not be unduly limited by the ground inductance. Furthermore, the scissor-type configuration of the probe of the invention enables the proximal ends of the substrates to be kept small in size to accommodate DUT layouts having small test features and/or test features that are close together.

A variety of probe device configurations are possible that will enable the goals of the invention to be achieved. A few examples of possible configurations will now be described with reference to the figures. It should be noted, however, that the invention is not limited to the probe device configurations described herein, as will be understood by persons skilled in the art in view of the following description and claims. It should also be noted that the figures are not necessarily drawn to scale. The figures are intended to demonstrate the principles and concepts of the invention without being limited in terms of dimensions or shape.

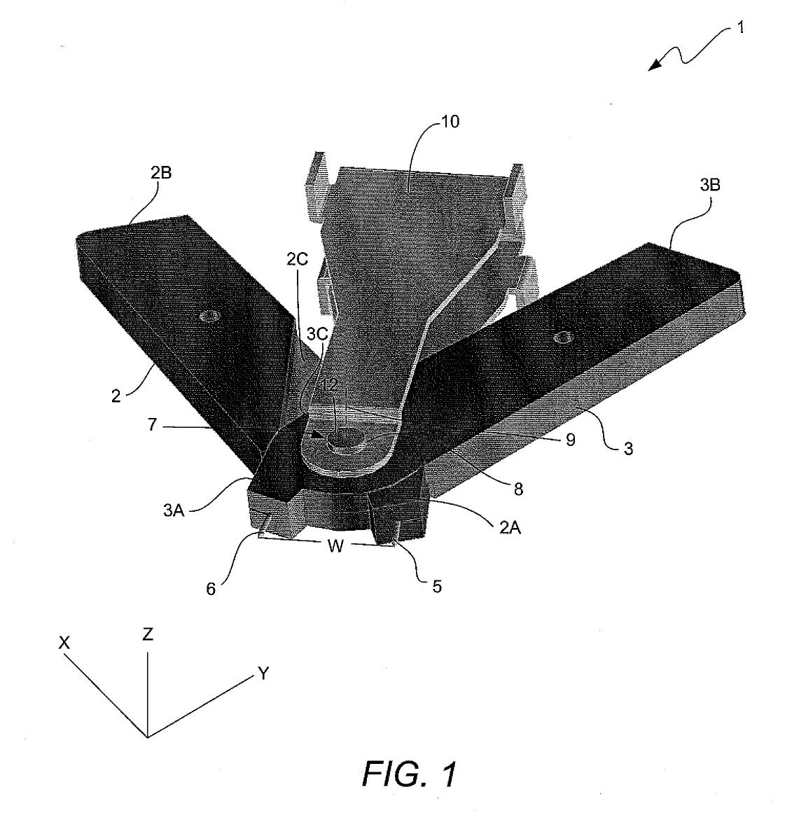

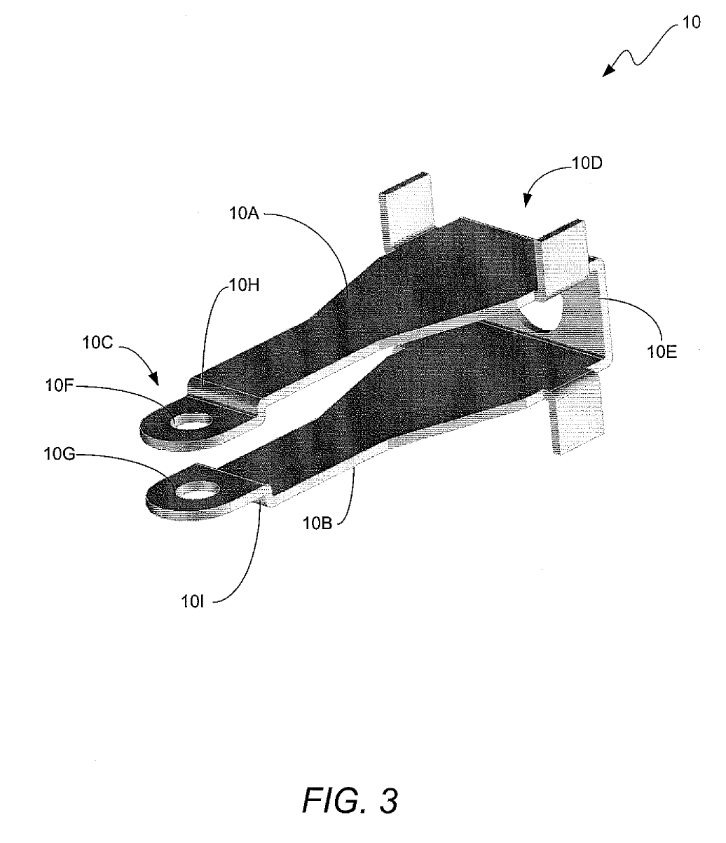

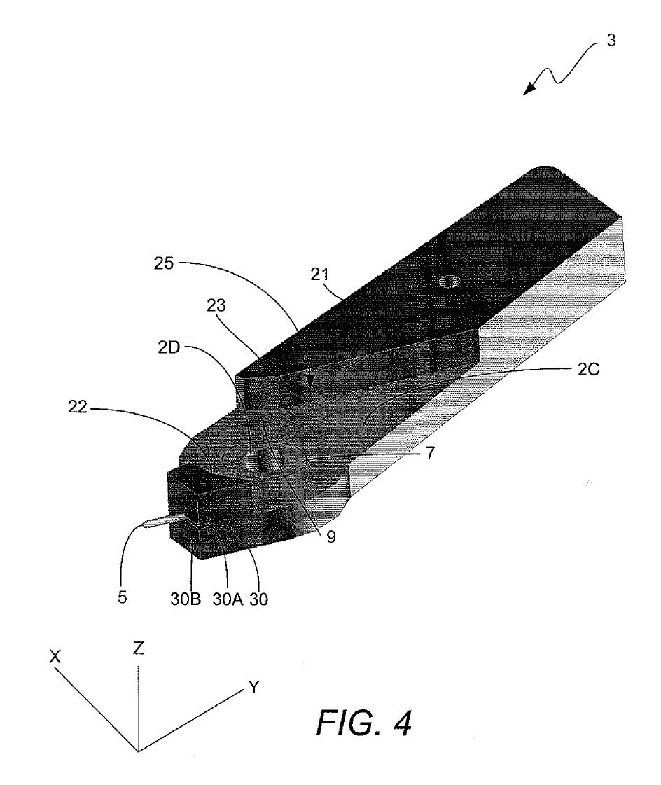

FIG. 1 illustrates a top perspective view of the differential probe device 1 of the invention in accordance with an illustrative embodiment. The differential probe device 1 has a scissor-type configuration comprising arms 2 and 3 having proximal ends 2A and 3A, respectively, and distal ends 2B and 3B, respectively. The proximal ends 2A and 3A of the arms 2 and 3 have conductive probe tips 5 and 6, respectively, secured thereto. The arms 2 and 3 are rotationally mechanically coupled to each other at a coupling point 7 near the proximal ends 2A and 3A by a coupling mechanism 8 that includes one or more coupling devices that allow the arms 2 and 3 to rotate about an axis 9. The coupling mechanism 8 will typically be a swivel mechanism, and so will be referred to interchangeably herein as the swivel mechanism 8 or the coupling mechanism 8. The axis 9 is normal to a X-Y plane and parallel to the Z-axis such that movement of the distal ends 2B and 3B in an X-Y plane away from each other results in movement of the proximal ends 2A and 3A in the X-Y plane away from each other, and vice versa. The swivel mechanism 8 is made up of one or more coupling devices including a cylindrical pin 12 and mating openings (not shown) formed in the probe device 1 that receive the pin 12, as will be described below in detail with reference to FIGS. 3 and 4.

The inner surfaces 2C and 3C of the arms 2 and 3, respectively, near the coupling point 7 are typically covered with an electrically conductive material, such as gold, for example, which function as electrical ground areas (not shown). The tips 5 and 6 are electrically connected to respective center conductors (not shown) of respective coaxial cables (not shown). The respective shields (not shown) of the respective coaxial cables function as grounds and are connected to the respective ground areas of the respective arms 2 and 3. These ground areas remain in continuous contact with each other as the proximal ends 2A, 3A and distal ends 2B, 3B move relative to each other. This region of contact between the ground areas and the tips 5 and 6 forms the inter-tip ground path. This feature of the invention eliminates the need for the aforementioned spring that is used with the aforementioned known differential probe device. In addition, because this region of contact between the ground areas is very near the probe tips 5 and 6, the length of the inter-tip ground path is extremely small. This feature of the invention ensures that the ground inductance will be small, and therefore will not unduly limit the bandwidth of signals that are measurable by the probe device 1, which is especially important at higher frequencies.

The coupling mechanism 8 couples the arms 2 and 3 to each other in a scissor-type configuration with the respective coupling areas 2C and 3C in contact with each other. This scissor-type configuration allows the arms 2 and 3 to rotate through a range of angles about the axis 9 in clockwise and counter-clockwise directions relative to the axis 9. Movement of the distal ends 2B and 3B away from each other results in movement of the proximal ends 2A and 3A away from each other. Movement of the distal ends 2B and 3B toward each other results in movement of the proximal ends 2A and 3A toward each other.

As described above, many known differential probe devices commonly used today have mechanical coupling devices that mechanically couple the arms to each other near their respective distal ends of the arms, i.e., at locations on the arms opposite the ends of the arms on which the probe tips are disposed. This makes it impractical to use the mechanical coupling point as a location for electrically interconnecting the ground areas on the arms. For example, if the inner surface of each arm had an electrical ground area thereon at the mechanical coupling point near the distal end of the arm, these ground areas would be in continuous contact with each other, but the point of contact between the ground areas would be so far away from the probe tips that long conductors would be needed to electrically connect the probe tips to the respective ground areas. These long conductors would result in a large ground inductance that would severely limit the bandwidth of the probe device. Such a configuration would also present spatial difficulties in terms of locating the other circuits that are needed on the substrates, e.g., the amplifier circuits. As stated above, in order to limit ground inductance, the ground areas for these types of probe devices are kept closer to the probe tips and the aforementioned conductive element (e.g., a spring mechanism) is used to electrically interconnect the ground areas. In addition, in these types of probe device configurations, if the mechanical coupling point for the arms is moved closer to the tip in an attempt to reduce ground inductance, the mechanics associated with span width adjustment generally will also need to be changed, which may result in the span width having less range.

With the scissor-type configuration of the invention shown in FIG. 1, the problems associated with the known probe device configuration described above are eliminated. In accordance with an embodiment, the probe device 1 includes a yoke 10 that is configured to preload the probe device 1 at the coupling point 7 with preloading forces that are exerted in opposite directions along the Z axis 9 to press the inner surfaces 2C and 3C of the arms 2 and 3, respectively, firmly against each other. These preloading forces ensure that continuous contact is maintained between the inner surfaces 2C and 3C at and around the coupling point, which ensures that the electrical ground areas are in continuous contact with each other over a range of span widths. The probe device 1 preferably is adjustable to allow the device 1 to operate over different span widths to accommodate different DUT layouts. The “span width”, as that term is used herein, is intended to denote the width, W, in the X-Y plane between the probe tips 5 and 6. Because the ground areas remain in continuous contact with each other regardless of the span width, the ground inductance remains very small and is substantially unchanged over the range of span widths. As stated above, this helps to ensure that the ground inductance remains relatively small and that the bandwidth of the probe device 1 is not unduly limited by the ground inductance.

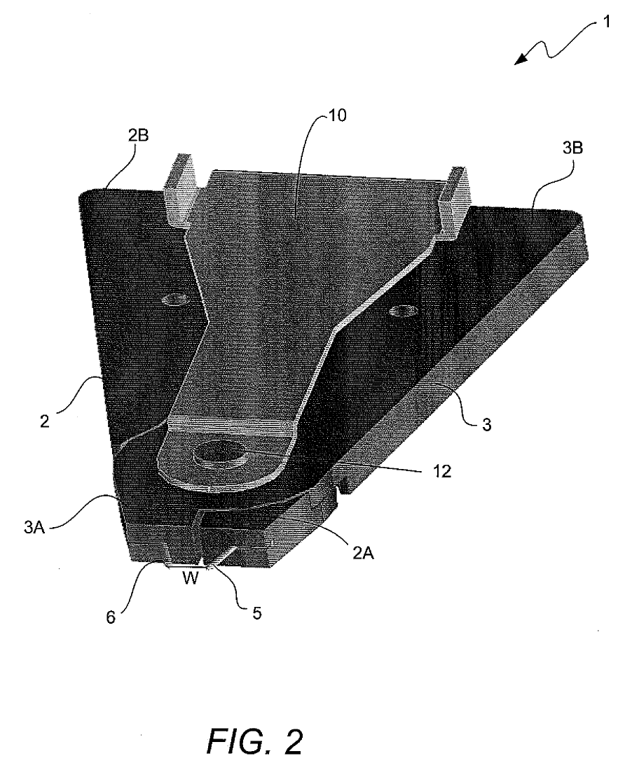

FIG. 2 illustrates a top perspective view of the differential probe device 1 of the invention shown in FIG. 1 when the distal ends 2B and 3B of the arms 2 and 3 are moved as close together as possible so that the span width W between the tips 5 and 6 is at a minimum value. In FIG. 1, the distal ends 2B and 3B are in a position at which they are as far away from each other as the swivel mechanism 8 will allow, and therefore the span width W is at a maximum value. The span width W may be set to a plurality of values that are between the maximum and minimum span width values. The minimum span width may be zero, although this cannot seen in FIG. 2. The invention is not limited to this particular configuration for adjusting the span width.

FIG. 3 illustrates a perspective top view of the yoke 10 of the probe device 1 shown in FIGS. 1 and 2. The yoke 10 has an upper portion 10A, a lower portion 10B, a proximal end 10C, a distal end 10D, and a connecting portion 10E. At the proximal end 10C, the upper and lower portions 10A and 10B of the yoke 10 have circular openings 10F and 10G, respectively, formed therein. The circular openings 10F and 10G are adapted to receive a cylindrical pin 12 (FIG. 2), which passes through cylindrical openings 2D and 3D (FIG. 4) formed in the proximal ends 2A and 3A of the arms 2 and 3, respectively. The combination of the cylindrical pin 12, the openings 10F and 10G formed in the yoke 10 and the openings 2D and 3D (FIG. 4) formed in the arms 2 and 3, respectively, forms the swivel mechanism 8 (FIG. 1).

The yoke 10 is formed of a substantially rigid material, such as sheet metal, for example. The upper and lower portions 10A and 10B have bends 10H and 10I formed in them, respectively. These bends are formed by bending the upper and lower portions 10A and 10B at angles that are preferably less than 90°. The location of these bends 10H and 10I at the proximal end 10C of the yoke 10 ensures that when the pin 12 has been inserted through the openings 10F and 10G formed in the yoke 10 and through the arms 2 and 3 of the probe device 1, the proximal end 10C of the yoke 10 will exert a preloading force on the proximal ends 2A and 3A of the arms 2 and 3, respectively. This preloading force ensures that the inner surfaces 2C and 3C of the arms 2 and 3, respectively, remain in continuous contact with each other over the entire range of span widths of the probe device 1.

In addition, this preloading force obviates the need to use other components to create a clamping force to force the inner surfaces 2C and 3C together, such as nuts, bolts and washers, for example. Consequently, the configuration of the yoke 10 reduces part count and thus allows the probe device 1 to be constructed in such a way that the proximal ends 2A and 3A of the arms 2 and 3, respectively, consume very little space. This feature of the invention allows the probe device 1 to connect to smaller features on a DUT and/or to features on the DUT that are very close together. Another advantage of the configuration of the yoke 10 is that the preloading force provided by the yoke allows the person testing the DUT to remove his or her hands without being concerned that the proximal ends will move, causing the span width to change.

FIG. 4 illustrates a top perspective view of the arm 2 of the probe device 1 shown in FIG. 1. The arm 3 shown in FIG. 1 is identical in shape and size to the arm 2 shown in FIG. 4 such that when the arms 2 and 3 are overlayed in the scissor-type configuration, the features of the arms 2 and 3 are complementary to each other. As shown in FIG. 4, the arm 2 has an angled wall 21 that abuts a like angled wall of the arm 3 (FIG. 1) when the distal ends 2B and 3B of the arms 2 and 3, respectively, are brought together. When these walls 21 abut, the span width W is at its minimum value. A facet 23 of the wall 21 abuts a portion of the arm 2 when the distal portions 2B and 3B of the arms 2 and 3 are rotated away from each other. At this position, the span width W is at its maximum value. At this position, the facet 23 acts as a stop that prevents further rotation of the arms 2 and 3. The arm 2 also includes a wall 22 that has a generally circular cross section that receives a feature (not shown) on the arm 3 that has a complementary circular cross section.

The walls 21-23 formed in the arms 2 and 3 are formed by removing complementary portions of the arms 2 and 3 to form the cutaway region 25 shown in FIG. 4. When the arms 2 and 3 are mechanically coupled to each other by the coupling mechanism 8 (FIG. 1), the cutaway regions 25 engage each other. Because the thicknesses (in the Z plane) of the cutaway regions 25 are equal for the arms 2 and 3, this ensures that when the cutaway regions 25 are engaged, the top and bottom surfaces of the probe device 1 are flat and that the tips 5 and 6 are aligned in the Z plane. This is an important feature of this embodiment of the invention because the tips 5 and 6 may be very difficult or impossible to see with the human eye. The tips 5 and 6 are essentially metal wires, and they are very difficult to see when they are very small in size. By ensuring that the tips 5 and 6 are aligned in the Z plane, it is ensured that the tips 5 and 6 are in very intuitive positions at the end of the probe device 1, which facilitates the task of placing the tips 5 and 6 in contact with the desired elements on the DUT. Without this feature of the invention, the tips would be in different positions with respect to the Z-axis, which would require that the user slightly rotate the probe device in order to maintain good contact between the tips and the elements on the DUT.

When the arms 2 and 3 are overlayed with their respective cutaway regions 25 engaged, the coupling mechanism 8 engages the arms 2 and 3 as follows; the pin 12 (FIG. 2) passes the opening 10F formed in the yoke 10 (FIG. 3); the pin 12 then passes through the opening 3D formed in the arm 3; the pin 12 then passes through the opening 2D formed in the arm 2; the pin 12 passes through the opening 10G formed in the yoke 10 (FIG. 3).

Another important feature of the embodiment of the invention illustrated in FIG. 4 is that the proximal ends 2A and 3A of the arms 2 and 3 have T slots 30 formed therein for receiving the tips 5 and 6, respectively. The tips 5 and 6 have shapes that are similar to that of a nail, i.e., an elongated portion with a tapered point on one end and a head on the other end. The head of the tip slides into the head-shaped portion 30A of the T slot 30 and the elongated portion of the tip slides into a tapered elongated portion 30B of the T slot 30. The portion 30B of the T slot 30 expands to allow the elongated portion of the tip to pass into the T slot 30 until it abuts the end of the tapered portion 30B, at which point the tapered portion 30B snaps back, like a latch, to retain the tip.

The tips 5 and 6 approach one another at an angle such that when a bending load that exceeds a predetermined bending moment is placed on one of the tips 5 and 6 by the feature it is in contact with on the DUT, the tip 5, 6 will pop out of the T slot 30, thereby preventing the tip 5, 6 from being damaged by excessive force. In the event the tip 5, 6 is damaged, it is easily replaceable by using tweezers to insert a new tip or to reinsert the tip that popped out of the T slot 30.

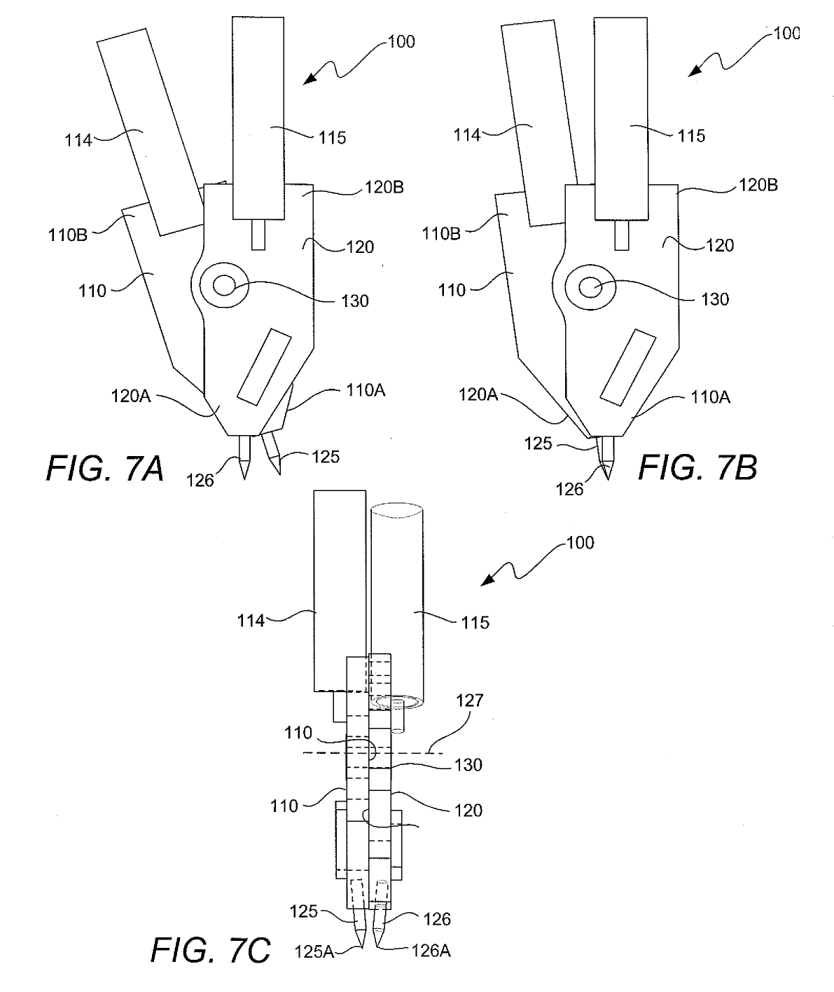

As described above, the cutaway regions 25 result in the probe device 1 having flat top and bottom surfaces when the arms 2 and 3 are engaged with each other. This configuration ensures that the tips 5 and 6 are aligned in the Z plane, which, as described above, is advantageous. The invention is not limited to this configuration for the probe device 1. For example, the probe device could be manufactured without the cutaway regions 25 of equal thicknesses, in which case the probe device 1 would not have flat upper and lower surfaces when the arms are engaged, as will be described below with reference to FIG. 7. Consequently, the tips 5 and 6 would not be aligned in the Z plane. However, such an alternative configuration would still work satisfactorily for many applications.

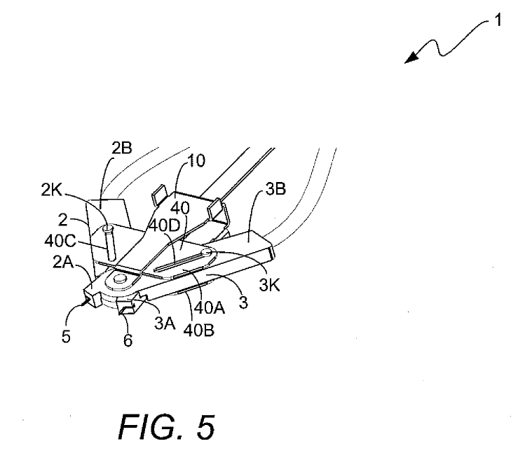

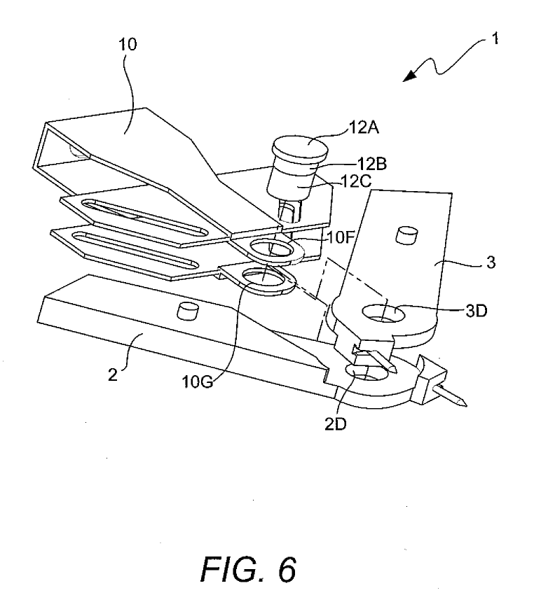

FIG. 5 illustrates a top perspective view of the probe device 1 shown in FIG. 1, but with a sliding mechanism 40 added to the probe device 1. The purpose of this sliding mechanism 40 is to allow the user to set the span width between the tips 5 and 6 at a selected value by sliding the sliding mechanism 40. The sliding mechanism 40 includes upper and lower plates 40A and 40B. At least the upper plate 40A has slots 40C and 40D formed therein for receiving pins 2K and 3K formed on the arms 2 and 3, respectively. The lower plate 40B may have like slots (FIG. 6) formed in it for receiving like tabs (not shown) on the sides of the arms 2 and 3 opposite the sides on which the pins 2K and 3K are disposed. The plates 40A and 40B are fixedly secured to one another (not shown) so that they move in tandem. The sliding mechanism 40 slides toward and away from the proximal ends 2A and 3A of the arms 2 and 3, respectively, while the yoke 10 remains stationary with reference to the sliding mechanism 40. The pins 2K and 3K engage and slide within the slots 40C and 40D, respectively. The user sets the span width between the tips 5 and 6 by either pushing or pulling the sliding mechanism 40 toward or away from the proximal ends 2A and 3A of the arms 2 and 3.

When the sliding mechanism 40 is pushed in a direction toward the proximal ends 2A and 3A, movement of the sliding mechanism 40 pushes the pins 2K and 3K in the same direction, thereby causing the distal ends 2B and 3B to be pushed apart and the proximal ends 2A and 3A to be pushed apart. When the sliding mechanism 40 is pulled in a direction toward the distal ends 2A and 3A, movement of the sliding mechanism 40 pushes the pins 2K and 3K in the same direction, thereby causing the distal ends 2B and 3B to be pulled together and the proximal ends 2A and 3A to be pulled together. Although not shown in FIG. 5, each of the slots 40C and 40D may have notches formed therein that are spaced apart by selected distances to enable the pins 2K and 3K to snap in place within the notches such that the notches define particular span widths between the tips 5 and 6. The notches may be labeled to allow the user to easily identify when the probe device 1 is at a selected span width.

FIG. 6 illustrates a perspective view of probe device 1 shown in FIGS. 1-5 with its parts disassembled to enable the manner in which the pin 12 and the swivel mechanism 8 interrelate to be more easily observed. As indicated above, the swivel mechanism 8, in accordance with this embodiment, includes the pin 12 and the openings that receive the pin 12, namely, circular openings 10F and 10G formed in the yoke 10 and cylindrical openings 2D and 3D formed in the arms 2 and 3. As described above, the pin 12 that passes through the openings 10F, 3D, 2D, and 10G to secure the arms 2 and 3 together in the scissor-type configuration. The pin 12 has a head 12A, a first shaft portion 12B and a second shaft portion 12C. The first shaft portion 12B of the pin 12 has a first diameter, D1. The second shaft portion 12C of the pin 12 has a second diameter, D2, which is smaller than diameter D1. The opening 10F formed in the yoke 10 has a diameter, D3, that is slightly larger than diameter D1 and significantly larger than diameter D2. The opening 10G formed in the yoke 10 has a diameter, D4, that is slightly larger than the diameter D2 and slightly smaller than the diameter D1. The openings 2D and 3D formed in the proximal ends 2A and 3A of arms 2 and 3, respectively, have diameters that are equal to the diameter D4 of the opening 10G formed in the yoke 10.

These diameters cause the swivel mechanism 8 to provide the following action. The first shaft portion 12B of the pin 12 (1) rotates freely within the opening 10F formed in the yoke 10, and (2) is press fit in the opening 3D formed in the proximal end 3A of the arm 3. The second shaft portion 12C of the pin 12 (1) rotates freely in the opening 2D formed in the proximal end 2A of the arm 2, and (2) slips within opening 10G formed in the yoke 10.

There are several advantages to the swivel mechanism 8. First, it allows the arms 2 and 3 to have identical configurations, which is an advantage for manufacturing in that an arm having only a single design needs to be manufactured. Second, the swivel mechanism 8 is made up of parts that require no special tools for assembly, due in large part to the forces exerted by the yoke 10 (FIG. 3). Third, if the probe device 1 is damaged, the swivel mechanism 8 can be easily disassembled in order to repair the probe device 1 or replace parts of the probe device 1. A user often has only a single probe device when making critical measurements, so the ability to easily disassemble and repair the device and then reassemble it is a very desirable feature. Fourth, all parts may be manufactured by standard manufacturing processes, which allows the overall cost of the probe device to be kept relatively low. Fifth, because it is possible to make the components of the coupling mechanism 8 very small in size, the probe device 1 can also be made very small in size to accommodate the ever-decreasing sizes of elements on DUTs. With known probe devices, the coupling mechanisms that are used to couple the arms together typically include C-clips, cotter pins and/or threaded fasteners. These types of devices are generally too large to incorporate into very small probe devices. Also, the extra material needed for these types of coupling mechanisms, particularly metals, can adversely affect performance.

FIGS. 7A-7C illustrate different views of a probe device 100 in accordance with another illustrative embodiment of the invention connected to coaxial cables 114 and 115. The probe device 100 comprises arms 110 and 120, each having a tip 125 and 126, respectively, secured thereto, and a coupling mechanism 130 that allows the arms 110 and 120 to rotate in clockwise and counter-clockwise directions about an axis 127 (FIG. 7C) that is normal to the surface of the coupling mechanism 130. Unlike the probe device 1 described above with reference to FIGS. 1-6, the arms 110 and 120 of the probe device 100 illustrated in FIGS. 7A-7C do not have cutaway regions (FIG. 4) that engage each other to cause the upper surface and the lower surfaces of the probe device 100 to be flat. Rather, the inner surfaces of the arms 110 and 120 are generally flat and abut each other when they are coupled together by the coupling mechanism 130.

In the front plan view of the probe device 100 illustrated in FIG. 7A, the distal ends 110B and 120B of the arms 110 and 120, respectively, have been rotated away from each other to the maximum extent allowed by the configuration, which causes the proximal ends 110A and 120A to be rotated away from each to the maximum extent allowed by the configuration. Therefore, the span width, W, between the tips 125 and 126 is at a maximum.

In the front plan view of the probe device 100 illustrated in FIG. 7B, the distal ends 110B and 120B of the arms 110 and 120, respectively, have been rotated toward each other to the maximum extent allowed by the configuration, which causes the proximal ends 110A and 120A to be rotated toward each to the maximum extent allowed by the configuration. Therefore, the span width, W, between the tips 125 and 126 is at a minimum.

In the side view of the probe device 100 illustrated in FIG. 7C, it can be seen that the tips 125 and 126 are not in the same plane as the arms 110 and 120, but are angled such that the ends 125A and 126A of the tips 125 and 126 contact one another when the probe device 100 is at the minimum span shown in FIG. 7B. Hence, it is unnecessary to rotate the probe device 100 as the span width changes in order to make contact with the DUT (not shown). It can also be seen in FIG. 7C that the inner surfaces 110C and 120C of the arms 110 and 120, respectively, are in contact with other at one or more locations, preferably at least at the proximal ends 110A and 120B. The arms 110 and 120 remain in continuous contact with each other at these locations over the allowed range of motion of the proximal and distal ends 110A, 120A and 110B, 120B.

Respective electrical ground areas are disposed on the inner surfaces 110C and 120C (FIG. 7C) of the arms 110 and 120 at the locations where the inner surfaces 110C and 120C are in continuous contact with each other. The respective electrical ground areas disposed on the inner surfaces 110C and 120C are connected to the respective ground shields of the respective coaxial cables (not shown). Because the inner surfaces 110C and 120C are in continuous contact, the respective ground areas on the arms 110 and 120 are also in continuous contact with each other over the entire range of span widths. The respective center conductors of the respective coaxial cables are connected to the respective tips 125 and 126. By locating the ground areas at the proximal ends 110A and 120A of the arms 110 and 120, the inter-tip ground path is kept very short, providing the aforementioned advantages.

It should be noted that the invention has been described with reference to illustrative embodiments for the purpose of describing the principles and concepts of the invention. Those skilled in the art will understand, in view of the description provided herein, that many modifications may be made to the embodiments described herein without deviating from the scope of the invention. For example, although the swivel mechanism 8 has been described with reference to a pin that mates with certain openings, this configuration could be replaced with a slot to allow a sliding motion rather than a rotating motion to be used to achieve the goals of the invention, as will be understood by those skilled in the art in view of the description being provided herein. These and other modifications may be made to the embodiments described herein, and all such modifications are within the scope of the invention.

What is claimed is:

1. A probe device for use in measuring electrical signals on a device under test (DUT), the probe device comprising:
first and second arms each having a proximal end and a distal end, the proximal ends of the first and second arms having first and second electrically conductive tips secured thereto, respectively, the first and second arms having first and second coupling areas disposed thereon, respectively, near the respective proximal ends, the first and second coupling areas having first and second electrical ground areas thereon, respectively, that are electrically connected to the first and second electrically conductive tips, respectively; and
a coupling mechanism coupling the first and second arms to each other in a scissor-type configuration with the first and second coupling areas in contact with each other, the scissor-type configuration allowing the first and second arms to rotate through a range of angles about an axis that is normal to the first and second coupling areas.

2. The probe device of claim 1, wherein the coupling mechanism allows the first and second arms to rotate about the axis in clockwise and counter-clockwise directions relative to the axis to allow the distal ends of the arms to move toward and away from each other over a first range of angular motion and to allow the proximal ends of the arms to move toward and away from each other over a second range of angular motion, wherein movement of the distal ends away from each other results in movement of the proximal ends away from each other, and wherein movement of the distal ends toward each other results in movement of the proximal ends toward each other.

3. The probe device of claim 2, wherein the first and second electrical ground areas remain in electrical contact with each other over the first and second ranges of angular motion.

4. The probe device of claim 3, wherein the first and second ranges of angular motion are equal.

5. The probe device of claim 2, wherein the coupling mechanism is a swivel mechanism comprising at least one coupling device that couples the first and second arms together in a way that allows the distal ends of the first and second arms to move toward and away from each over the first range of angular motion and that allows the proximal ends of the first and second arms to move toward and away from each over the second range of angular motion.

6. The probe device of claim 5, wherein said at least one coupling device includes at least a pin that is received in at least one opening formed in at least one of the first and second arms.

7. The probe device of claim 1, further comprising:
a yoke having an upper portion, a lower portion, a proximal end, and a distal end, the proximal end of the yoke being mechanically coupled to the proximal ends of the first and second arms by the coupling mechanism, the yoke exerting a preloading force on the proximal ends of the first and second arms that presses the first and second coupling areas against each other to ensure that the first and second electrical ground areas remain in contact with each other as the arms rotate about the axis over the range of angles.

8. The probe device of claim 7, wherein the coupling mechanism is a swivel mechanism, the swivel mechanism comprising:
a pin having a head and a shaft;
a first opening formed in the proximal end of the yoke for receiving a portion of the shaft;
an opening formed in the proximal end of the second arm for receiving a portion of the shaft that passes through the first opening formed in the proximal end of the yoke;
an opening formed in the proximal end of the first arm for receiving a portion of the shaft that passes through the opening formed in the proximal end of the second arm; and
a second opening formed in the proximal end of the yoke for receiving a portion of the shaft that passes through the opening formed in the proximal end of the first arm, wherein the first and second openings formed in the proximal end of the yoke and in the proximal ends of the first and second arms are coaxially aligned with the axis about which the first and second arms rotate.

9. The probe device of claim 8, wherein the shaft has a first shaft portion and a second shaft portion, the first shaft portion having a first diameter, D1, and the second shaft portion having a second diameter, D2, the first opening formed in the proximal end of the yoke and the opening formed in the proximal end of the second arm receiving the first shaft portion, the opening formed in the proximal end of the first arm and the second opening formed in the proximal end of the yoke receiving the second shaft portion, and wherein the first and second openings formed in the proximal end of the yoke and the openings formed in the proximal ends of the first and second arms each have a diameter that is chosen such that the first shaft portion rotates freely within the first opening formed in the proximal end of the yoke and is press fit in the opening formed in the proximal end of the second arm, and such that the second shaft portion rotates freely in the opening formed in the proximal end of the first arm and slips within second opening formed in the proximal end of the yoke.

10. The probe device of claim 8, further comprising:
a sliding mechanism having first and second plates that are connected to each other in a substantially parallel arrangement, at least the first plate having first and second slots formed therein for receiving first and second tabs, respectively, disposed on the first and second arms, respectively, and wherein the sliding mechanism is configured to slide relative to the yoke in directions toward and away from the distal ends of the first and second arms, and wherein sliding the sliding mechanism toward the distal ends of the first and second arms causes the distal ends of the first and second arms to rotate toward each other and the proximal ends of the first and second arms to rotate toward each other, and wherein sliding the sliding mechanism away from the distal ends of the first and second arms causes the distal ends of the first and second arms to rotate away from each other and the proximal ends of the first and second arms to rotate away from each other.

11. The probe device of claim 1, wherein the first and second arms have first and second cutaway regions, respectively, formed therein at and around the first and second coupling areas, respectively, the first cutaway region being complementary of the second cutaway region, the first and second cutaway regions having equal thicknesses such that when the first and second arms are coupled to each other by the coupling mechanism, the first and second cutaway regions engage each other to provide the probe device with a flat top surface and a flat bottom surface.

12. The probe device of claim 11, wherein a span width, W, between the first and second electrically conductive tips is adjustable by rotating the first or second arms such that the proximal ends of the arms are brought closer together or are farther apart.

13. The probe device of claim 12, wherein the first and second electrically conductive tips remain at least substantially in a common plane throughout adjustments made in the spam width, W.

14. The probe device of claim 1, wherein the first and second electrically conductive tips are removably secured to the proximal ends of the first and second arms, respectively, such that the tips can be removed and replaced.

15. The probe device of claim 14, wherein each tip has an elongated portion and a head, the elongated portion of the tip having a first end connected to the head and a second end at which the elongated portion becomes a tapered point, the proximal ends of the first and second arms each having a T-shaped slot formed therein for receiving the first and second tips, respectively, wherein the elongated portions of the tips slide into tapered elongated portions of the respective T-shaped slots and wherein the heads of the tips slide into head-shaped portions of the respective T-shaped slots.

16. The probe device of claim 15, wherein if a bending moment exceeding a predetermined bending moment is exerted on either of the tips, the tip on which the bending moment is exerted will be pushed out of the respective T-shaped slot to prevent the tip from being damaged by the excessive bending moment.

17. A method for manufacturing a probe device for measuring electrical signals on a device under test (DUT), the method comprising:
providing a probe device having at least a first arm, a second arm and a coupling mechanism, the first arm having a proximal end and a distal end, the proximal ends of the first and second arms having first and second electrically conductive tips, respectively, secured thereto, the first and second arms having first and second coupling areas, respectively, disposed thereon near the respective proximal ends, the first and second coupling areas having first and second electrical ground areas thereon, respectively, the first and second electrical ground areas being electrically connected to the first and second tips, respectively; and
using the coupling mechanism to couple the first arm and the second arm to each other at the first and second coupling areas in a scissor-type configuration with the first and second coupling areas in contact with each other, wherein the scissor-type configuration allows the first and second arms to rotate about an axis that is normal to the first and second coupling areas through a range of angles.

18. The method of claim 17, wherein the coupling mechanism allows the first and second arms to rotate about the axis in clockwise and counter-clockwise directions relative to the axis to allow the distal ends of the arms to move toward and away from each other over a first range of angular motion and to allow the proximal ends of the arms to move toward and away from each other over a second range of angular motion, wherein movement of the distal ends away from each other results in movement of the proximal ends away from each other, and wherein movement of the distal ends toward each other results in movement of the proximal ends toward each other.

19. The method of claim 18, wherein the first and second electrical ground areas remain in electrical contact with each other over the first and second ranges of angular motion.

20. The method of claim 19, wherein the first and second ranges of angular motion are equal.

21. The method of claim 18, wherein the coupling mechanism is a swivel mechanism comprising at least one coupling device that couples the first and second arms together in a way that allows the distal ends of the first and second arms to move toward and away from each over the first range of angular motion and that allows the proximal ends of the first and second arms to move toward and away from each over the second range of angular motion.

22. The method of claim 21, wherein said at least one coupling device includes at least a pin that is received in at least one opening formed in at least one of the first and second arms.

23. The method of claim 17, further comprising:
providing the probe device with a yoke having an upper portion, a lower portion, a proximal end, and a distal end, the proximal end of the yoke being mechanically coupled to the proximal ends of the first and second arms by the coupling mechanism, the yoke exerting a preloading force on the proximal ends of the first and second arms that presses the first and second coupling areas against each other to ensure that the first and second electrical ground areas remain in contact with each other as the arms rotate about the axis over the range of angles.

24. The method of claim 23, wherein the coupling mechanism is a swivel mechanism, the swivel mechanism comprising:
a pin having a head and a shaft;
a first opening formed in the proximal end of the yoke for receiving a portion of the shaft;
an opening formed in the proximal end of the second arm for receiving a portion of the shaft that passes through the first opening formed in the proximal end of the yoke;
an opening formed in the proximal end of the first arm for receiving a portion of the shaft that passes through the opening formed in the proximal end of the second arm; and
a second opening formed in the proximal end of the yoke for receiving a portion of the shaft that passes through the opening formed in the proximal end of the first arm, wherein the first and second openings formed in the proximal end of the yoke and in the proximal ends of the first and second arms are coaxially aligned with the axis about which the first and second arms rotate.

25. A method of using a probe device to measure electrical signals on a device under test (DUT), the method comprising:
adjusting a span width, W, between first and second electrically conductive tips of a probe device by moving distal ends of first and second arms of the probe device toward or away from each other to cause proximal ends of the first and second arms of the probe device to move toward or away from each other, respectively, the first and second electrically conductive tips being secured to the proximal ends of the first and second arms, respectively, wherein movement of the distal ends of the arms away from each other results in movement of the proximal ends away from each other such that the span width, W, is increased, and wherein movement of the distal ends toward each other results in movement of the proximal ends toward each other such that the span width, W, is decreased; and
positioning the probe device such that the first and second electrically conductive tips are in contact with one or more features on the DUT.
